(19) United States
(12) Patent Application Publication
(10) Pub. No.: US 2026/0215205 A1
(43) Pub. Date: Jul. 23, 2026

(54) FUNCTIONALIZED PADS FOR CHEMICAL PLANARIZATION

(71) Applicant: CHEMPOWER CORPORATION, Beaverton, OR (US)

(72) Inventors: Sudhanshu Misra, Camas, WA (US); Suryadevara Babu, Portland, OR (US); Roger Allan Berge, El Dorado Hills, CA (US)

(21) Appl. No.: 19/452,033

(22) Filed: Jan. 16, 2026

Related U.S. Application Data
(60) Provisional application No. 63/746,612, filed on Jan. 17, 2025.

(51) Int. Cl. H10P 72/00

(52) U.S. Cl. CPC H10P 72/0428

(57) ABSTRACT

Examples are disclosed that relate to a pad for performing abrasive-free chemical planarization of a substrate. The pad comprises a polymer layer configured to contact the substrate during the abrasive-free chemical planarization. The polymer layer comprises a plurality of reactive units covalently bonded within polymer chains. Each reactive unit comprises a functional group comprising one or more of a complexing agent or a hydrolyzing agent for performing the abrasive-free chemical planarization. The polymer layer comprises a plurality of molded grooves each containing turbulence-creating structures configured to cause turbulence in a planarization solution within the grooves during a planarization process.

### CROSS REFERENCE TO RELATED APPLICATIONS

This application claims priority to U.S. Provisional Application 63/746,612, entitled “PADS FOR CHEMICAL PLANARIZATION” and filed Jan. 17, 2025, the entirety of which is hereby incorporated herein by reference for all purposes.

### BACKGROUND

Chemical mechanical planarization (CMP) is commonly used in integrated circuit fabrication processes to smooth surfaces, such as that of a semiconductor substrate, by removal of material using a combination of chemical and mechanical forces. A typical CMP process involves using an abrasive and a chemical slurry that can be corrosive to the material being removed, in combination with a polishing pad. The substrate and polishing pad are pressed together, and rotated relative to one another with non-concentric axes of rotation. The combination of the force and slurry removes areas of the substrate with a higher topology compared to areas with a lower topology, thereby smoothing the surface.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

Examples are disclosed that relate to pads for performing abrasive-free chemical planarization of a substate. One example provides a pad comprising a polymer layer configured to contact the substrate during the abrasive-free chemical planarization. The polymer layer comprises a plurality of reactive units covalently bonded within polymer chains. Each reactive unit comprises a functional group comprising one or more of a complexing agent or a hydrolyzing agent for performing the abrasive-free chemical planarization. The polymer layer comprises a plurality of molded grooves each containing turbulence-creating structures configured to cause turbulence in a planarization solution within the grooves during a planarization process.

Another example provides a pad for performing abrasive-free chemical planarization of a substrate. The pad comprises a first polymer layer configured to contact the substrate during the abrasive-free chemical planarization. The first polymer layer comprises a plurality of reactive units covalently bonded within polymer chains. Each reactive unit comprises a functional group comprising one or more of a complexing agent or a hydrolyzing agent for performing the abrasive-free chemical planarization. The pad further comprises a second polymer layer positioned on an opposite side of the first polymer layer as a substrate-contacting side of the first polymer layer.

Another example provides a pad for performing abrasive-free chemical planarization of a substrate. The pad comprises a polymer layer located configured to contact the substrate during the abrasive-free chemical planarization. The polymer layer comprises a plurality of reactive units covalently bonded within polymer chains. Each reactive unit comprises a functional group comprising one or more of a complexing agent or a hydrolyzing agent for performing the abrasive-free chemical planarization. The pad further comprises groove structures configured to provide compressibility for the pad.

### BRIEF DESCRIPTION OF THE FIGURES

FIG. 1 shows a block diagram of an example chemical planarization system.

FIG. 2A shows a schematic depiction of an example pad for performing chemical planarization.

FIG. 2B shows the example pad of FIG. 2A and illustrates contact between topologically higher portions of a substrate and an upper layer of the pad.

FIG. 3 shows a schematic depiction of another example pad for performing chemical planarization.

FIG. 4 shows a schematic depiction of another example pad comprising a textured substrate-facing surface.

FIGS. 5A-5B schematically illustrate examples of incorporation of a functional group into a polymer.

FIG. 6 illustrates examples of monomers that can be used to form a pad for chemical planarization.

FIGS. 7A-7B show a flow diagram depicting an example method of forming a pad for chemical planarization.

FIG. 8 shows a schematic depiction of another example pad for performing chemical planarization.

FIGS. 9A-9H show a schematic depiction of another example pad for performing chemical planarization.

### DETAILED DESCRIPTION

While current methods of CMP find use in a wide variety of device fabrication contexts, current CMP methods also pose various drawbacks. For example, current CMP processes are relatively dirty compared to other fabrication processes, due at least in part to the use of conditioner chemicals, as well as the abrasive slurry and pad that mechanically abrade the material during planarization. Defects generated by CMP can be large yield loss contributors to fabs. Defects and scratches generated during CMP may largely originate from the mechanical components in the process, such as the abrasives in the slurry, the force of the pad against the substrate, pad conditioning, and tribological aspects of the process. Further, the slurry contains abrasives that can scratch device layers, thereby creating pits and leaving residues that can become killer defects. Additionally, pad debris is generated during polish and pad conditioning. Such pad debris can create particles and agglomerates that contaminate the substrate being processed. Also, the force of the pad against the wafer can cause pad deformation. This can result in shear stresses at interfaces from intimate contact with the substrate and relative motion between the substrate and pad. Further, CMP processes may not be predicable, and thus may be dominated by trial-and-error approaches, rather than analytical approaches. Further still, the handling, delivering and stabilization of slurries can pose difficulties for fabrication facilities due to solid content. This can increase facilities maintenance costs. As a result, conventional CMP processes can require redundancy in deposition and over polishing, which can lead to wasted resources, increased costs, and lower productivity.

Accordingly, examples are disclosed herein that relate to pads for performing planarization chemically, without the dirty and defect-prone mechanical processes used in conventional CMP methods. Briefly, the disclosed examples utilize an abrasive-free planarization chemistry at a pad instead of an abrasive slurry. The term “abrasive-free” indicates a planarization chemistry without a mechanically abrasive solid component for removing substrate material by abrasion. The disclosed pads comprise at least one polymer layer configured to contact the substrate during the abrasive-free chemical planarization. The polymer layer comprises a plurality of reactive units covalently bonded within polymer chains. Each reactive unit comprises a functional group comprising one or more of a complexing agent or a hydrolyzing agent for performing the abrasive-free chemical planarization.

Using the disclosed pads, the substrate can be controlled to contact topologically higher features of the substrate to the pad, and not contact topologically lower features of the substrate. Planarization chemistry is exposed to portions of the substrate in contact with the pad, thereby selectively removing material from those portions of the substrate. In this manner, the topology of the substrate surface may be made smoother without using abrasives, and by applying relatively light pressure against the substrate. This may help to avoid scratching or otherwise damaging the device layer, thereby helping to avoid defects and potentially improving yields over conventional CMP processes.

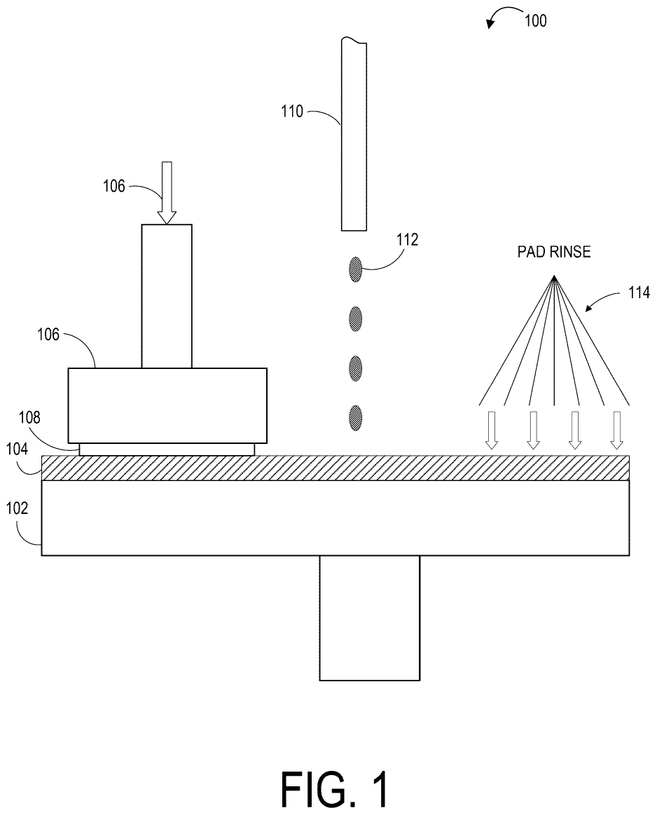

Prior to discussing the disclosed examples of abrasive-free planarization pads, FIG. 1 shows a schematic depiction of an example chemical planarization system 100 according to the present disclosure. System 100 comprises a platen 102 that supports a pad 104. The system 100 further includes a substrate holder 106 configured to hold a substrate 108 against the surface of the pad 104, and a planarization solution introduction system 110 for introducing a planarization solution 112 onto the pad 104. The system 100 further may comprise a pad rinsing system 114 configured to rinse possible contaminant materials from the pad 104, such as complexed materials that have been removed from the surface of the substrate 108. Pad rinsing system 114 also may be used to clean the pad between using different planarization solution chemistries, as described below. Other components (not shown) that may be incorporated into system 100 include, but are not limited to, a spent solution recovery system, a materials recirculation system (e.g., for recirculating the planarization solution in a closed loop process), and a species stripping system.

In conventional CMP processes, the substrate holder pushes the substrate against a polishing pad supported on a platen, and the pad and the substrate are rotated relative to one another in a non-concentric pattern. In such conventional processes, relatively high rates of rotations are used, such as between 40-100 rpm. Further, the substrate is pushed against the pad with a relatively high pressure, such as in a range of 1-4 pound per square inch. In contrast, a lighter pressure can be used in the disclosed examples, including but not limited to pressures in the range of 0.25 to 0.75 pounds per square inch. The lighter pressure may avoid distortion of the pad shape, and may reduce shear stresses compared to conventional CMP processes. Likewise, a slower rate of rotation may be used in the disclosed examples than with conventional CMP processes, as the rotational motion is not used for abrasion. Instead, rotation of the platen 102 helps to distribute planarization fluid across the pad 104. Any suitable rate of rotation may be used. Examples include rates in a range of 0-60 rpm. More specific examples include rates of 5-30 rpm. As mentioned above, the rate of rotation may be lower than a rate at which a platen rotates in a conventional CMP process, as the rotational motion is not being used in the examples herein to abrade material from a substrate. It will be understood that many different configurations and designs are possible for a variety of platform types (rotary, linear or belt style, vertically, rollers, hollow fibers).

The planarization solution may comprise chemical components to hydrolyze a substrate material (e.g. by oxidation and dissolution). The planarization solution may be configured to remove any suitable materials. As one example, polysilicon may be removed via a planarization solution comprising poly(diallyldimethylammonium chloride) (PDADMAC) in deionized water. In some such examples, the PDADMAC solution may be mixed with oxalic acid and/or hydrogen peroxide, and further may comprise a suitable acid or alkaline agent (e.g. nitric acid or potassium hydroxide) to adjust the pH. Other reagents also may be used to planarize polysilicon, including but not limited to poly(dimethylamine-co-epichlorohydrin-co-ethylenediamine), poly(allylamine), and poly(ethylene imine) (PEI). In other examples, one or more metals such as copper, molybdenum, ruthenium, rhenium, rhodium, and cobalt, as examples, may be removed using a planarization solution comprising hydrogen peroxide and guanidine carbonate, again with pH adjusters to achieve a desired solution pH. As another example, ammonium persulfate may be used for removal of suitable metals (e.g., cobalt), with pH adjusters to achieve a desired solution pH. Other examples of suitable hydrolyzing agents may include, but are not limited to, nitric acid, sulfuric acid, hydrochloric acid, phosphoric acid, ammonium hydroxide, sodium hydroxide, and potassium hydroxide.

In some examples, the planarization solution may comprise additional components. For example, the planarization solution may comprise complexing/chelating agents to transport removed material from the substrate after hydrolysis. Examples of suitable chelating agents may include, but are not limited to, ethylenediaminetetraacetic acid (EDTA), sulfosalicylic acid, naphthol (PAN), dithizone, organophosphorus acid esters, polyethylene glycol, amines, and thioxine. Further, in some examples, the planarization solution may comprise passivating agents and/or corrosion inhibitors. Examples include, but are not limited to, benzatriazoles (BTA), ammonium dodecyl sulfate (ADS), tolyltriazoles (TTA), thiols (e.g. PTAT (5-(phenyl)-4H-1,2-4-triazole-3-thiol)), thiodiazoles, carboxylic acids, benzoic acid, and ammonium benzoate. Other examples of materials that may be included in the planarization solution include, but are not limited to, surfactants, surface modifiers other than passivation and/or corrosion inhibitors, catalysts, thermally activated chemicals, light activated chemicals, species tracers, additives, and stabilizers.

Inhibitors such as BTA can help to achieve planarization by suppressing removal rates at low topography areas of a wafer. However, BTA and other corrosion inhibitors can be hazardous and may also pose environmental challenges during disposal. Furthermore, BTA may complicate the process of cleaning wafers after polishing, as it can interact with other substances (e.g., nano-abrasives) in conventional CMP processes to create residues on the wafers that are difficult to remove. As described in more detail below, functionalized pads can selectively polish high topography areas without the use of added inhibitors. This results in a cleaner process and obviates additional post-planarization cleaning steps.

In some examples, hydrolyzing agents and complexing agents are bonded to functionalized polymers of the pad, as described in more detail below. In some such examples, the planarization solution dispensed onto the pad may include deionized water, and the chemical planarization may be performed by the functionalized polymers. In other such examples, the planarization solution may include additional components other than deionized water.

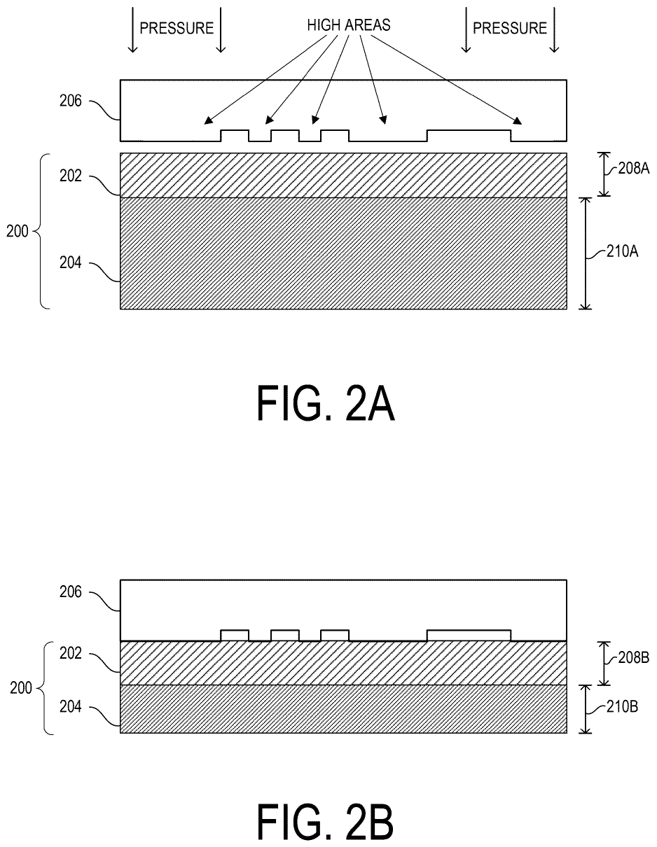

FIGS. 2A-2B show a schematic view of an example pad 200 that is suitable for use as pad 104. The pad 200 includes a first polymer layer 202 and a second polymer layer 204. The first polymer layer 202 is configured to contact substrate 206 during abrasive-free chemical planarization. The second polymer layer 204 is positioned on an opposite side of the first polymer layer 202 as a substrate-contacting side of the first polymer layer 202. Such a dual layer structure may be used to implement a multi-sequence material removal and separation process, wherein the steps comprise one or more chemical steps-hydrolysis (and potential dissolution) of the species being removed, oxidation, hydroxylation, ionization, and radical formation- and chemical complexation of the species being removed, based upon a chemical formulation of the pad and a composition of the planarization solution. Further, the first polymer layer 202 and the second polymer layer 204 can be configured to have other functionalities. For example, the second polymer layer can be configured to be compressible. As such, when the first polymer layer 202 is brought into contact with substrate 206 during a chemical planarization process, the second polymer layer 204 can compress to avoid applying unwanted pressure against the substrate 206. In some such examples, both hydrolysis and complexation are configured to occur in a same layer (e.g., the first polymer layer 202). Further, the first polymer layer can comprise a textured surface in some examples, as described in more detail below.

The first layer and second layer may be joined together in any suitable manner. In some examples, the first layer and the second layer are joined by an adhesive. In other examples, one of the first layer or second layer is insert molded into the other of the first layer or the second layer. In yet other examples, one or both of the first layer or the second layer can be additively manufactured. In yet further examples, the first layer and the second layer can be formed in a same molding or casting process, but wherein the composition of the material being molded or cast is changed mid-pour or mid-injection. In such examples, by virtue of having dissimilar characteristics between the top layer and the bottom layer, this constitutes an asymmetric medium. Such an asymmetric medium may, in some examples, include a gradual and systematic variation in characteristics, or may transition abruptly at the interface of two layers. This enables control over compressibility and other mechanical characteristics of the first polymer layer 202 and/or the second polymer layer 204. In other examples, the two layers will be integrated and seemingly compose a composite pad. Furthermore, the pad 200 may be adhered or otherwise joined to an additional sub-layer, such as a woven textile matrix or soft polymer sheet (e.g., sub-pads of the type currently used for conventional CMP polishing pads).

In some examples, polymer phase inversion or phase separation may be used to form such an asymmetric structure. In other examples, vapor induced phase separation (air casting) may be used. As yet another example, liquid induced phase separation (immersion casting) may be used by dissolving polymer in solvent at room temperature and immersing in liquid non-solvent to induce phase separation. This enables different morphologies including asymmetric membranes. Methods for forming an asymmetrical structure (e.g. a multi-layer porous matrix) include manipulating phase separation conditions during single layer casting, casting a small pore size membrane on a large pore size substrate, casting multi-layers of different pore sizes contemporaneously, laminating different pore size layers together, and utilizing temperature induced phase separation (TIPS or melt casting) (in which a polymer is heated above melting point and dissolved in porogens, and phase separation induced by cooling).

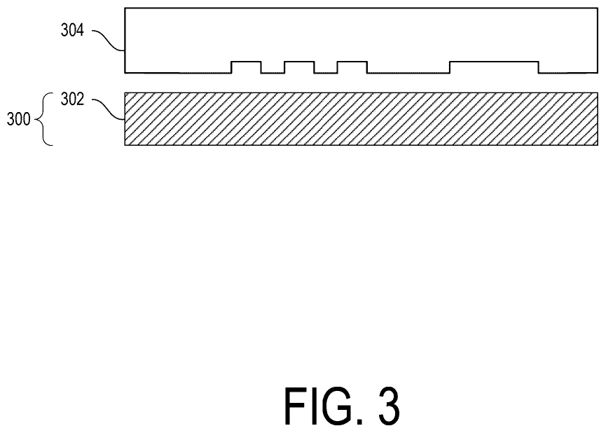

In other examples, the pad comprises a single polymer layer. FIG. 3 shows a schematic view of another example pad 300 that is suitable for use as the pad 104 of FIG. 1. The pad 300 comprises a single polymer layer 302 configured to contact substrate 306. In some such examples, both hydrolysis and complexation are configured to occur in a same layer. In yet other examples, a pad comprises three or more layers.

Referring again to FIGS. 2A-2B, in some examples, the first polymer layer 202 may be relatively thin compared to the second pad, and may be configured for hydrolysis (e.g., oxidation of metal species in some examples) of materials being removed in the planarization process. As such, the first polymer layer 202 may comprise relatively larger pores, may be hydrophilic, and may be surface modified to functionalize the polymer surface, thereby allowing the polymer of the first polymer layer 202 to participate in hydrolysis reactions. In some such examples, the first layer may have a thickness in a range of 0.1 micron to five microns thick. In other examples, the first layer can have any other suitable thickness (e.g., a thickness of less than 0.1 microns or greater than five microns). In yet other examples, the first polymer layer 202 can be nonporous. For example, and as described in more detail below, the first polymer layer may comprise a textured surface that provides additional surface area for the abrasive-free planarization chemistry.

In some examples, the second polymer layer 204 may be relatively thicker than the first layer, and may have relatively smaller pores than the first layer. In some examples, the second layer may be configured to retain materials removed by the first layer. For example, the second layer may comprise a surface that is chemically modified with metal complexing agents adsorbed or bonded to the second layer within the pores to retain metal ions removed from the substrate. In some examples, the second layer may have a thickness of several microns to 3 mm thick, and in more specific examples, from 40 microns to 2 mm thick.

FIGS. 2A-2B also depict contact between a substrate 206 and the pad 200. As shown in FIGS. 2A-2B, topologically higher regions of the substrate 206 contact the pad 200, and the pad 200 does not contact topologically lower regions of the substrate. The use of relatively little pressure of the substrate 206 against the pad 200, combined with the planarization chemistry being located within the pad 200 instead of in the space between the pad and substrate, helps to achieve removal of material from the topologically higher regions of the substrate 206 at a higher rate compared to, or even to the exclusion of, the topologically lower regions, as the topologically higher regions are in contact with the hydrolyzing and/or complexing environment in the pad.

In FIGS. 2A-2B, pressure is applied via the substrate 206 that presses the substrate 206 against the pad 200. In some examples, the pad 200 is compressed merely by a weight of the substrate 206. In other examples, additional force is applied to the substrate 206 (e.g., via the substrate holder 106 of FIG. 1) to press the substrate 206 against the pad 200. Such force(s) can cause compression of the pad 200 as shown in FIG. 2B. In some examples, as introduced above, the second polymer layer 204 is configured to provide compressibility while the first polymer layer 202 can have a porous and/or textured surface configured to remove material during the abrasive-free chemical planarization process.

Further, the first and/or second layer may be designed with mechanical attributes such that it is rigid enough to handle the wafer load and the down force/applied pressures. In some examples, the first polymer layer and/or a second polymer layer may have a storage modulus of 15 MPa to 1200 MPa. More specific examples include storage moduli of 400-800 MPa. In some examples, the first polymer layer and/or the second polymer layer have a loss modulus of 100-600 MPa. More specific examples include loss moduli of 150-500 MPa. In some examples, the first polymer layer and/or a second polymer layer have a Tan delta (loss divided by storage) of 0.2-0.9. More specific examples include 0.4-0.8. In some examples, the first polymer layer and/or a second polymer layer have a compressibility of <5%, and/or a surface tension of less than 40 mN/m. The viscoelastic characteristics and physical attributes of the first polymer layer and/or the second polymer layer can be determined by standard dynamic mechanical analysis (DMA), differential scanning calorimetry (DSC) and thermogravimetric analysis (TGA) methods.

In some examples, as mentioned above, the second polymer layer 204 is more compressible than the first polymer layer 202. The first layer polymer 202 has a thickness 208A in FIG. 2A before compression. The first polymer layer 202 has a second thickness 208B after compression that is substantially the same as the first thickness 208A. In contrast, the second polymer layer 204 has a first thickness 210A before compression. The second polymer layer 204 has a second thickness 210B in FIG. 2B that is less than the first thickness 210A of FIG. 2A. In this manner, the second polymer layer 204 may absorb compressive force while the first polymer layer 202 maintains a planar substrate-facing surface. In other examples, the first polymer layer 202 is more compressible than the second polymer layer 204. In this manner, the second polymer layer 204 can serve as a relatively firm “bed” that supports the first polymer layer 202 against the substrate 206.

The first and second layers may comprise any suitable material or materials. In some examples, the first polymer layer 202 and/or the second polymer layer 204 may comprise one or more of polyurethane, polyanhydride, polycarbonate, polyacrylate, polysulfone, polyester, polyacrylonitrile, polyethersulfone, polyarylsulfone, polyacrylonitrile, epoxy, and/or polyvinylidene fluoride. Further, in some examples, the first layer and/or the second layer may have a 60-90 shore A hardness or 30-60 shore D hardness. In other examples, the first layer and/or second layer may have hardness values outside of these ranges. All ranges stated herein are inclusive of endpoint values.

In some examples, the first layer comprises a thermoplastic material and the second layer comprises a thermoset material. In some such examples, the second polymer layer 204 can be formed from a thermoset polymer with more crosslinking than the first polymer layer 202. As described in more detail below, the thermoplastic material can be 3D-printed on the second polymer layer 204 or otherwise formed in a more controlled manner than casting or injection molding. This enables fine control over the structure and physical characteristics of the pad. In further examples, both the first layer and the second layer can be formed from a thermoset material, or both layers can be formed from a thermoplastic material.

As mentioned above, the first layer and/or the second layer can optionally comprise a porous polymer. In some examples, pores are formed in the first layer and/or the second layer utilizing TIPS or melt casting. Other techniques to form pores within the polymer include introducing a blowing agent such as steam and/or other gases (e.g., air, carbon dioxide, or nitrogen) to form bubbles in the molten polymer before it solidifies.

In some more specific examples, the first polymer layer 202 has a smaller pore fraction than the second polymer layer 204. For example, the first layer may have an average pore size in a range of 1 nm to 1000 nm, preferably 30 nm to 200 nm. The second layer may also have an average pore size in a range of 5 nm to 1000 nm, preferably 200 nm to 1000 nm. In such examples, the second polymer layer 204 can provide suitable compressibility to accommodate deformation of the first polymer layer 202. In other examples, the first polymer layer 202 has a greater pore fraction than the second polymer layer 204. In yet other examples, one or more of the first polymer layer 202 and/or the second polymer layer 204 is nonporous.

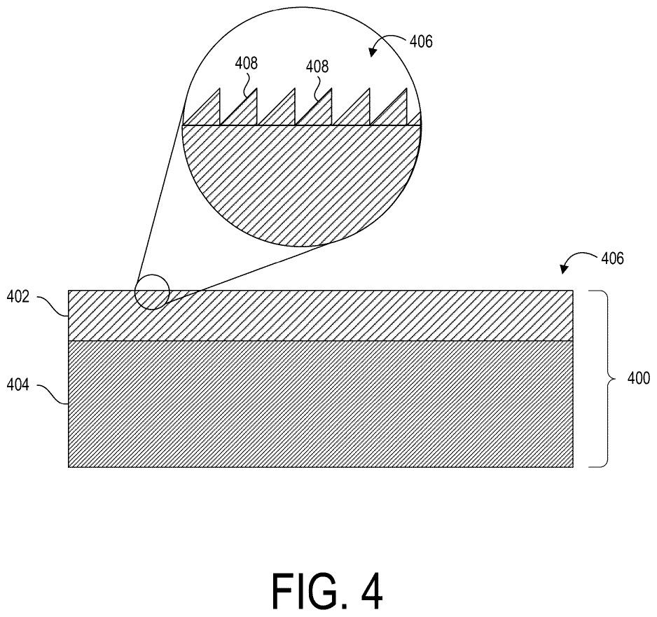

In some examples, the first layer comprises a textured substrate-facing surface. FIG. 4 shows a schematic view of another example pad 400 that is suitable for use as the pad 104 of FIG. 1. The pad 400 includes a first polymer layer 402 and a second polymer layer 404. The first polymer layer 402 comprises a textured substrate-facing surface 406 configured to contact a substrate during abrasive-free chemical planarization. The textured substrate-facing surface 406 comprises a plurality of structures 408, such as bumps, ridges, or grooves, that can cause friction between the pad 400 and the substrate, which can lead to the removal of material from the substrate. In addition, the textured surface can compensate for a lack of porosity by providing surface area for chemical reactions and/or channels that conduct planarization fluid during processing.

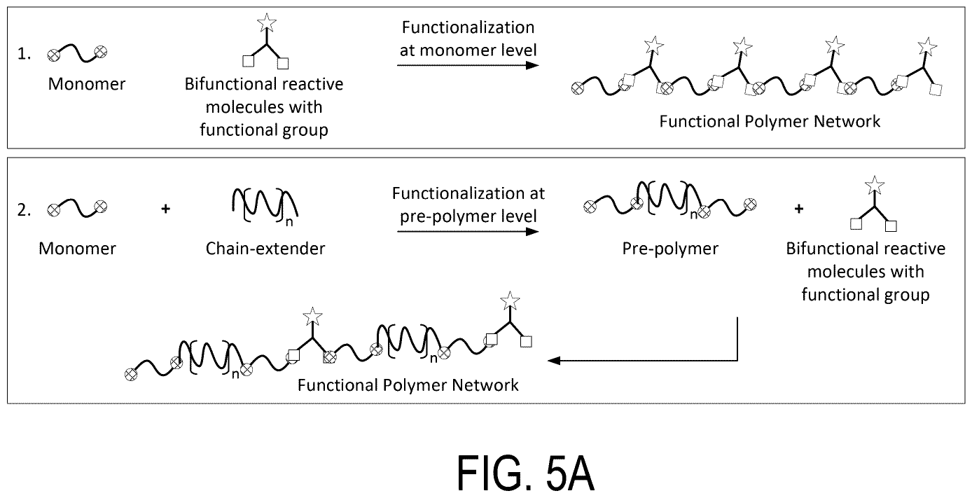

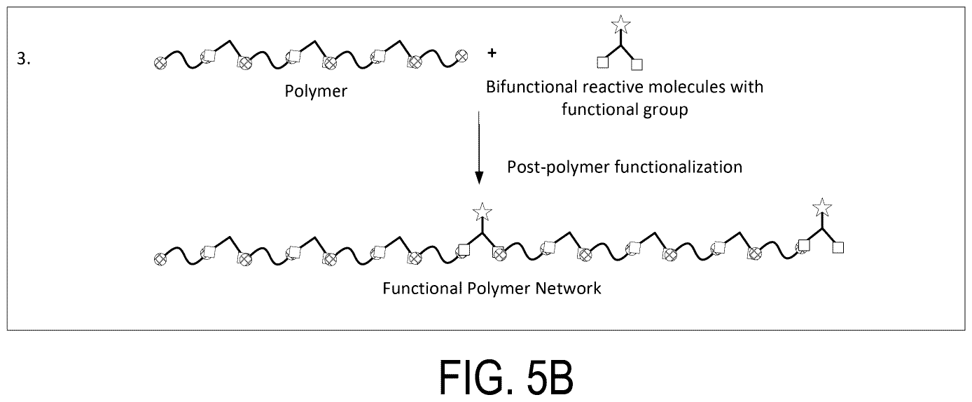

As described in more detail below with reference to FIGS. 5A-5B, the first polymer layer and/or the second polymer layer comprise a plurality of reactive units covalently bonded within polymer chains. Each reactive unit comprises a functional group. FIGS. 5A-5B schematically illustrate incorporation of the functional group into the polymer. In some examples, the functional group comprises a hydrolysis and/or a complexation agent for performing abrasive-free chemical planarization. In some examples, the functional groups comprise one or more of a carboxylic acid, an amine, a sulfonic acid, an alcohol, a phosphonic acid, an amide, or a polyethylene. In some more specific examples, the functional groups comprise one or more of iminodisuccinic acid, ethylenediaminedisuccinic acid, glutamic acid, methylglycinediacetic acid, dicyanamide, or polydiallyldimethylammonium chloride. Such species can also be used as chelating agents separate from a pad, in addition to or alternatively to the functionalization of a pad with such species. In other examples, any other suitable functionalization may be performed to impart any desired chemical functionality to the pad. Other examples of functional groups include, but are not limited to, —COOCH₂CH₂OH, —N(CH₂CH₂OH)₂, and —CONHR.

In some examples, the polymer layer comprises a hybrid of a covalently bonded functional group and a distribution of functional groups freely dispersed in the polymer matrix. In this manner, dispersed species can be released upon contact with a planarization solution to assist in planarization. For example, oxalic acid can be dissolved into a polymer blend during pad manufacturing so that it can be released into polish media during planarization. The two-COO groups from oxalic acid assist in Cu complexation enhancing the removal of Cu. In this manner, a covalently functionalized pad may enhance material removal rates. Furthermore, a process can be operated repeatedly without reconditioning the pad since abrasives are not used, as long as the dispersed species is not limiting and the pad surface asperities maintain integrity upon multiple polish cycles. In the event a conditioning process is used to mechanically abrade the pad, the polish process will remain abrasive-free. In some such approaches where abrasive conditioning is implemented, the pad may include surface grooves or channels to facilitate removal of polymer debris during conditioning. Since there are no abrasives, the advantage still holds for a low-defect polish process. The environmental benefits are valid during the polish process as the effluent can be chemically treated for species and water recovery. Polymer residues from abrasive conditioning may be separated prior to any environmental disposal.

Any suitable method may be used to functionalize the polymers of the pad. In some examples, polymers of the pad can be functionalized during polymer synthesis. FIGS. 5A-5B schematically illustrates incorporation of the functional group into the polymer. In scheme (1), a monomer is linked to a bifunctional reactive molecule that contains a target functional group. Polymerization results in distribution of the target functional group throughout the polymer (including within a solid mass of the polymer). In this manner, the functional groups are incorporated homogeneously throughout the polymer layer. One potential advantage of this approach is the presence of functional groups at pore surfaces throughout the pad. Furthermore, mechanical wear and/or chemical degradation reveals additional functional groups below the substrate-facing surface, enabling the pad to operate longer than a pad lacking interior functional groups. In addition, a single layer pad may be manufactured in a single step, thereby decreasing manufacturing time and costs relative to a pad having two or more layers.

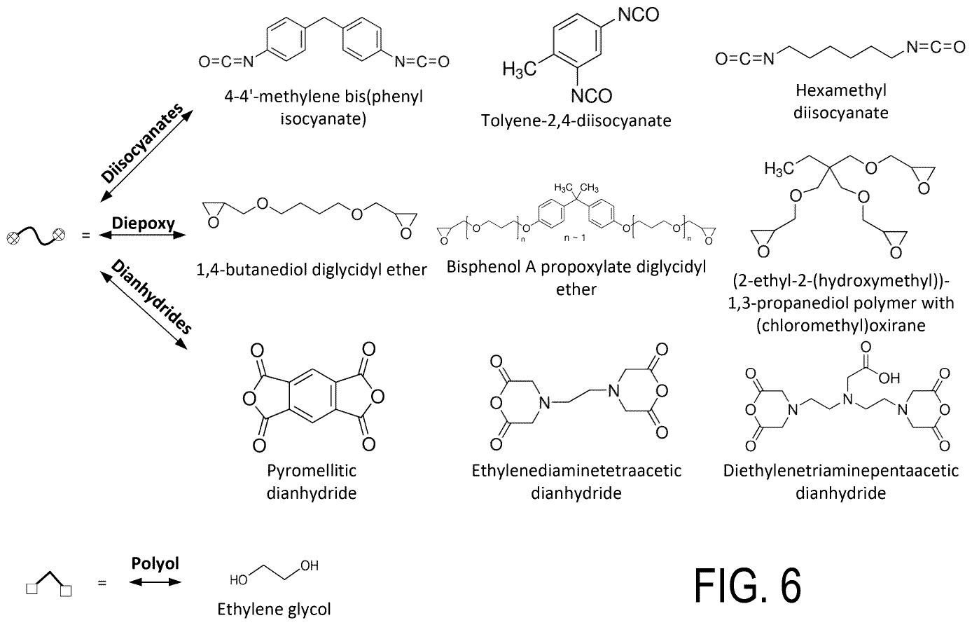

Monomers that are suitable for generating a cross-linked polymer network with curing agents or functionalized reactive molecules include monomers which possess at least two reactive sites. As illustrated by way of example in FIG. 6, some examples of suitable monomers include diisocyanates (e.g., 4,4′-methylene bis(phenyl isocyanate), tolyene-2,4-diisocyanate, and hexamethyl diisocyanate), diepoxies (e.g., 1,4-butanediol diglycidyl ether, bisphenol A propoxylate diglycidyl ether, and (2-ethyl-2 (hydroxymethyl))-1,3-propanediol polymer with (chloromethyl) oxirane), and anhydrides (e.g., pyromellitic dianhydride, ethylenediaminetetraacetic dianhydride, and diethylenetriaminepentaacetic dianhydride). In some examples, such monomers react with ethylene glycol and/or substituted forms of ethylene glycol (e.g., glyceric acid) to form a polyurethane that contains un-reacted carboxylic acid groups. These carboxylic acids can serve as chelating ligands for Cu removal during the polishing process.

In some examples, the polymer layer comprises a polyurethane. In some such examples, the functional groups are located on an isocyanate moiety of the polyurethane. Reaction of a hydroxyl group or an amine group with the isocyanate can create the urethane linkage of the polymer backbone. Some examples of suitable molecules that can react with diisocyanate monomers include polyols (e.g., glyceric acid). In some such examples, the functional groups are located on a polyol moiety of the polyurethane. Other examples of suitable molecules that can react with diisocyanate monomers include 2-2′-bis(hydroxymethyl) propionic acid and 3,4-dihydroxybenzoic acid. In some such examples, an acid moiety can serve as a chelating functional group (e.g., for Cu removal during a polishing process).

In other examples, the polymer layer can comprise a polyurea and a polyurethane. As described above, the functional groups can be located on an isocyanate moiety of the polyurethane or on a polyol moiety of the polyurethane. Reaction of a hydroxyl group or an amine group with the isocyanate can create the urethane linkage of the polymer backbone. Further, in some such examples, a curing agent can be used for generating a cross-linked polymer network. Example curing agents include diamine curing agents and diol curing agents. In examples where the curing agent comprising a diamine curing agent, reaction of the diamine curing agent with the isocyanate of the polyurea can create a urea linkage of the polymer backbone.

In further examples, the polymer layer comprises a polyanhydride. In some such examples, the functional groups are located on an anhydride moiety of the polyanhydride. Polyanhydrides can be formed by condensation between two carboxylic acid groups, resulting in the elimination of a water molecule. The anhydride moieties render polyanhydrides more reactive and more prone to hydrolysis than other polymers (e.g., polyurethane). This can result in a biodegradable polymer network that reduces environmental impact of waste materials. In some such examples, the polyanhydride further comprises polyol moieties covalently linked with the polyanhydride. In some such examples, the functional groups are additionally or alternatively located on the polyol moieties. Polyols can be incorporated into polyanhydride-based systems as additives or modifiers. For example, polyols can be used as plasticizers to increase flexibility of the polyanhydride. Polyols can also be employed as components in copolymers, such as a copolymer including a polyanhydride linkage and a polyester linkage. This can result in a hybrid material with customized properties (e.g., flexibility and compressibility) tuned for chemical planarization.

In other examples, the functional polymer network is additionally or alternatively formed using a curing agent and/or a cross-linking agent that contains the target functional group. In some such examples, one or more curing agents can be utilized. Examples of suitable curing agents include diamine curing agents and diol curing agents.

In yet other examples, functional polymers are cross-linked with a cross-linking agent that does not contain the target functional group. Cross-linking results in a three-dimensional polymer network that is stronger and more rigid than unlinked polymers.

In some such examples, the polymer layer comprises an epoxy. The epoxy can be formed by treating precursor molecules comprising epoxide functional groups with a curing agent. The curing agent causes crosslinking of the precursor molecules to form a three-dimensional network structure. In some such examples, the functional groups are located on an epoxide moiety of the epoxy. In other examples, the functional groups are additionally or alternatively located on a curing agent and/or a polyol bound within an epoxy chain. As described above, polyols can be incorporated into a polymer layer to tailor one or more properties of the polymer, such as flexibility and toughness, viscosity, adhesion, and hydrophobicity. In some examples, addition of a polyol or other additive can change the rate or extent of cross-linking, which can also be used to tailor the properties of the polymer.

Referring again to FIGS. 5A-5B, in some examples, the functional groups are separated by oligomeric segments of the polymer chain. For example, in scheme (2), the monomer is linked to a chain extender to form an extended pre-polymer molecule. The extended pre-polymer molecule is polymerized in the presence of a bifunctional reactive molecule containing the target functional group to form a functional polymer network as shown in FIGS. 5A-5B. As a result, the functional group is incorporated into the polymer network at extended intervals, where the pre-polymer molecules are joined together.

The polymer can be additionally or alternatively functionalized after polymerization. Scheme (3) shows an example of post-polymerization functionalization. For example, a bifunctional reactive molecule containing the target functional group can be linked to a synthesized polymer. In some such examples, the functional groups are bound to a substrate-facing surface of the polymer layer. For example, the functional groups can be bound to a substrate-facing surface of the first polymer layer 202 of FIGS. 2A-2B. As one example, a polyvinylidene fluoride (PVDF) porous layer or other suitable layer may be functionalized with a chelating agent such as poly(acrylic acid) to complex metal ions after removal from the substrate. The PVDF porous layer may be used either for a first layer or second layer in the example of FIGS. 2A-2B.

In some examples, the first polymer layer 202 of FIGS. 2A-2B is functionalized and the second polymer layer 204 is not functionalized. This can result in cost savings and faster and/or more efficient manufacturing than functionalizing the entire pad. In other examples, as described above, two or more surfaces of the pad can be functionalized, which can additionally or alternatively include one or more surfaces of the first polymer layer 202 and the second polymer layer 204. It will also be appreciated that the first polymer layer and/or the second polymer layer may comprise different functional groups.

In some examples, the polymer may be functionalized by coating, in which the functional groups are not cross-linked to the polymer substrate, but instead adsorbed. For example, the polymer may be functionalized by adsorbing reactive molecules containing the functional groups using a suitable solvent system. The solvent system can, in some examples, cause swelling of the polymer layer that allows the functional groups to be incorporated into at least a portion of a bulk volume of the polymer layer.

Additionally, where functionalized polymers are used for the pads, the functionalization may be regenerated, for example, by adding new functional groups in-situ (e.g., through the planarization solution dispensing mechanism) to regenerate the functional groups. Additional aspects of regenerating the functionalization are described in more detail in U.S. patent application Ser. No. 17/729,805 entitled PAD SURFACE REGENERATION AND METAL RECOVERY, filed on Apr. 26, 2022, the entire contents of which are hereby incorporated by reference for all purposes.

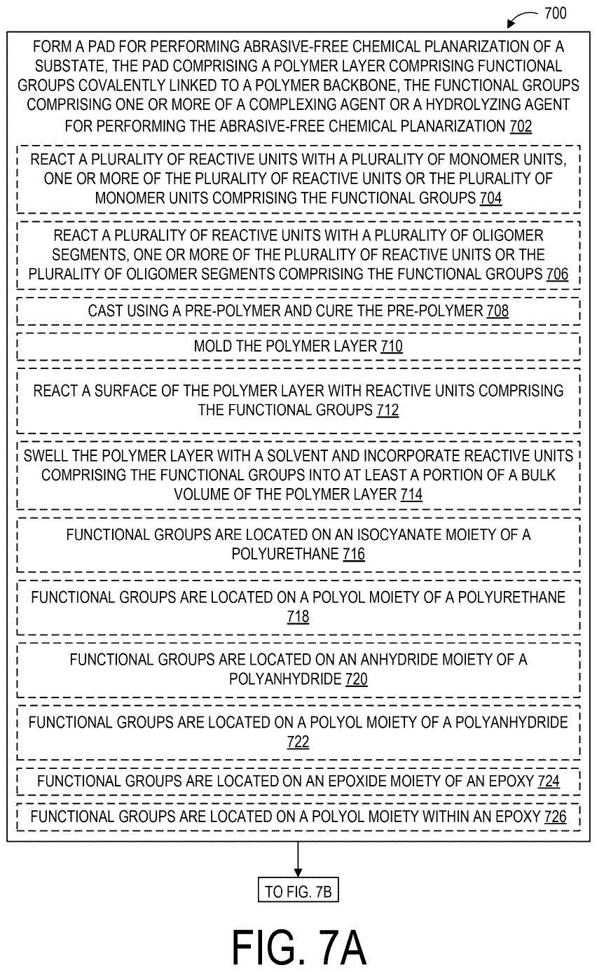

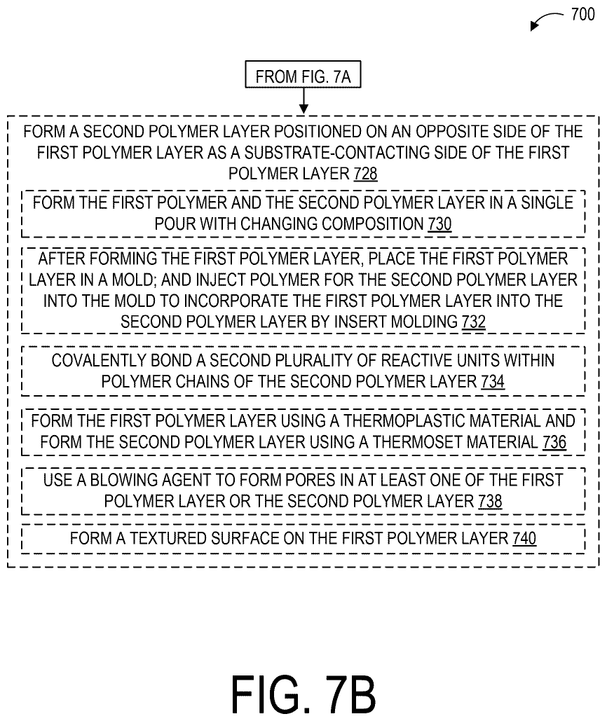

FIGS. 7A-7B show a flow diagram depicting an example method 700 of forming a pad for performing abrasive-free chemical planarization of a substate. The following description of the method 700 is provided with reference to FIGS. 1-6 above. It will be appreciated that the method 700 also can be performed in other contexts.

At 702, the method 700 comprises forming a pad for performing abrasive-free chemical planarization of a substate. The pad comprises a polymer layer comprising functional groups covalently linked to a polymer backbone, the functional groups comprising one or more of a complexing agent or a hydrolyzing agent for performing the abrasive-free chemical planarization. FIGS. 2A-2B show an example of a pad 200 that can be formed by the method 700 of FIGS. 7A-7B.

The pad may be formed in any suitable manner. In some examples, at 704, forming the pad comprises reacting a plurality of reactive units with a plurality of monomer units, one or more of the plurality of reactive units or the plurality of monomer units comprising the functional groups. FIGS. 5-6 illustrate some examples of suitable monomers. In scheme (1) of FIGS. 5A-5B, polymerization of a monomer with a bifunctional reactive molecule comprising a target functional group results in distribution of the target functional group throughout the polymer.

In other examples, at 706, forming the pad comprises reacting a plurality of reactive units with a plurality of oligomer segments, one or more of the plurality of reactive units or the plurality of oligomer segments comprising the functional groups. For example, in scheme (2) illustrated in FIGS. 5A-5B, a monomer is linked to a chain extender to form an extended pre-polymer molecule. The extended pre-polymer molecule is polymerized in the presence of a bifunctional reactive molecule containing the target functional group to form a functionalized polymer.

In some examples, at 708, forming the pad comprises casting the polymer layer using a pre-polymer and curing the pre-polymer. For example, a pre-polymer may be formed as described above with reference to FIGS. 5A-5B. The pre-polymer may be more viscous than a solution of monomer units and may therefore be easier to handle and pour into molds than the monomer units. This allows for straightforward and efficient casting processes, especially for complex or intricate shapes. Pre-polymers can be formulated with specific compositions and properties to control factors such as hardness, flexibility, elongation, and curing time. Pre-polymers can be designed to cure at ambient temperature or with minimal heat input, simplifying the casting process. This can enable the polymer to be cured at a lower temperature, reducing energy consumption and enabling casting in molds that are sensitive to heat. Furthermore, since pre-polymers can be manufactured in controlled conditions, the use of a pre-polymer can result in more homogenous batch-to-batch production than polymerization from scratch. Casting with pre-polymers also allows for precise metering and control of material usage. This minimizes material waste and contributes to cost-effectiveness in production.

Any suitable curing agent can be used to cure the pre-polymer. Examples of suitable curing agents include diamine curing agents and diol curing agents. In some examples, one or more curing agents can be utilized. As a specific example, a mono curative process can utilize a diamine curing agent to form a urea linkage to the prepolymer. As another example, a dual curative process can utilize a diamine curing agent to form a urea linkage to the prepolymer and a diol curing agent to form a urethane linkage to the prepolymer.

At 710, in some examples, forming the pad comprises molding the polymer layer. For example, a pre-polymer can be molded as described above to form the polymer layer.

In some examples, at 712, forming the pad comprises reacting a surface of the polymer layer with reactive units comprising the functional groups. For example, the functional groups can be bound to a substrate-facing surface of the first polymer layer 202 of FIGS. 2A-2B.

At 714, in some examples, forming the pad comprises swelling the polymer layer with a solvent and then incorporating reactive units comprising the functional groups into at least a portion of a bulk volume of the polymer layer. For example, the polymer layer can be treated with a solvent system that causes swelling of the polymer layer. This enables the functional groups to be incorporated into at least a portion of a bulk volume of the polymer layer.

In some examples, at 716, forming the polymer layer comprises forming a polyurethane, wherein the functional groups are located on an isocyanate moiety of the polyurethane. For example, as described above with reference to FIG. 6, the functional groups can be located on an isocyanate, such as 4,4′-methylene bis(phenyl isocyanate), tolyene-2,4-diisocyanate, and hexamethyl diisocyanate. Reaction of a hydroxyl group or an amine group with the isocyanate can create the urethane linkage of the polymer backbone. In this manner, the functional groups can be integrated into the polyurethane.

At 718, in some examples, forming the polymer layer comprises forming a polyurethane, wherein the functional groups are located on a polyol moiety of the polyurethane. For example, as described above, a polyol can be reacted with an isocyanate to form a polyurethane. The functional groups can be provided on the polyol to thereby incorporate the functional groups into the polyurethane.

In some examples, at 720, forming the polymer layer comprises forming a polyanhydride, wherein the functional groups are located on an anhydride moiety of the polyanhydride. For example, as described above with reference to FIG. 6, the functional groups can be located on an anhydride, such as pyromellitic dianhydride, ethylenediaminetetraacetic dianhydride, and diethylenetriaminepentaacetic dianhydride. In this manner, the functional groups can be incorporated into a polyanhydride.

At 722, in some examples, forming the polymer layer comprises forming a polyanhydride, wherein the functional groups are located on a polyol moiety of the polyanhydride. For example, polyols can be incorporated into polyanhydride-based systems as additives or modifiers. In this manner, providing the functional groups on a polyol results in the functional groups being incorporated into the polymer layer.

In some examples, at 724, forming the polymer layer comprises forming an epoxy, wherein the functional groups are located on an epoxide moiety of the epoxy. For example, as described above with reference to FIG. 6, the functional groups can be located on an epoxy. Cross-linking of the epoxies thereby results in formation of a polymer containing the functional groups.

At 726, in some examples, forming the polymer layer comprises forming an epoxy, wherein the functional groups are located on a polyol bound within an epoxy chain. The polyol can serve as the curing agent or an additive/modifier. Polymerization thereby incorporates the polyol and the functional groups into the polymer matrix.

Referring now to FIG. 7B, in some examples, at 728, the method 700 further comprises forming a second polymer layer positioned on an opposite side of the first polymer layer as a substrate-contacting side of the first polymer layer. In some examples, the first polymer layer 202 and the second polymer layer 204 are integrally constructed as a bilayer during a single process. In some such examples, the first polymer layer 202 and the second polymer layer 204 are formed by liquid casting, injection molding, extrusion, additive manufacturing, or a combination thereof.

In some examples, at 730, forming the first polymer and the second polymer layer comprises forming the first polymer and the second polymer layer in a single pour with changing composition. For example, a composition of a liquid poured into a mold during a liquid casting process can be changed partway through the liquid casting process. This results in an integral structure having two distinct layers produced during a single process, which enables the composition and other properties of the porous pad to be tuned during manufacturing. The use of a single process to form both layers also reduces cost and increases process efficiency relative to forming each layer separately.

In other examples, the first polymer layer 202 and the second polymer layer 204 are fabricated in separate steps. In some such examples, the first polymer layer 202 and the second polymer layer 204 are formed by liquid casting, injection molding, extrusion, additive manufacturing, or a combination thereof.

In some examples, at 732, the method 700 further comprises, after forming the first polymer layer, placing the first polymer layer in a mold. The method 700 further comprises injecting polymer for the second polymer layer into the mold to incorporate the first polymer layer into the second polymer layer by insert molding. This enables inspection of the first layer before forming the second layer and can allow for finer control over the formation of the first layer and the second layer. In some examples, it can be faster, cheaper, and/or more efficient to fabricate the first layer and the second layer separately than in a single step as described above.

At 734, in some examples, the method 700 comprises covalently bonding a second plurality of reactive units within polymer chains of the second polymer layer. For example, the second polymer layer 204 of FIGS. 2A-2B can be functionalized in the same manner as described above.

In some examples, at 736, forming the first polymer layer comprises forming the first polymer layer using a thermoplastic material, and forming the second polymer layer comprises forming the second polymer layer using a thermoset material. For example, the first polymer layer 202 of FIGS. 2A-2B may comprise a thermoplastic material and the second polymer layer 204 may comprise a thermoset material, or vice versa. This enables each layer to have a tunable molecular structure and physical characteristics (e.g., compressibility and toughness).

At 738, in some examples, the method 700 comprises using a blowing agent to form pores in at least one of the first polymer layer or the second polymer layer. This enables formation of a porous polymer structure, which can have a larger surface area (including surfaces of the pores) and greater compressibility than a solid polymer.

In some examples, at 740, the method 700 comprises forming a textured surface on the first polymer layer. For example, the pad 400 of FIG. 4 comprises a textured substrate-facing surface 406. The textured surface can accelerate removal of material from a substrate and increases surface area relative to a smooth substrate-facing surface.

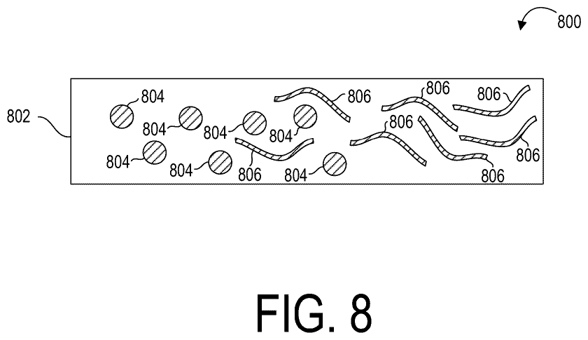

FIG. 8 shows a schematic view of another example pad 800 that is suitable for use as the pad 104 of FIG. 1. The pad 800 comprises a single polymer layer 802. However, as described above, in other examples, the pad 800 may comprise any other suitable number of layers (e.g., two or more layers). The pad 800 comprises a plurality of microspheres 804 and/or a plurality of fillers 806. The microspheres 804 and/or the fillers 806 are dispersed through the polymer layer 802 during pad manufacturing. The microspheres 804 and the fillers 806 each comprise a polymer and functional groups (e.g., the functional groups described above with reference to FIGS. 5-6) bonded to the polymer. However, the microspheres 804 and the fillers 806 are not covalently bonded to the polymer layer 802 of the pad 800. Instead, the microspheres 804 and the fillers 806 can be held within the polymer layer 802 by electrostatic forces, hydrophilic/hydrophobic interactions, Van der Waals forces, mechanical interlocking, etc. Furthermore, the microspheres 804 and the fillers 806 can be regenerated chemically. This enables repeated use of the functional groups for multiple wafers.

As mentioned above, a planarization pad can include grooves to aid the distribution of an abrasive-free planarization solution. Presently, pads are grooved with relatively simple designs, such as concentric circles, radial grooves or, alternatively, structures focused on contact with the wafer. Further, the grooves are typically formed by cutting into the planarization pad after casting. In contrast to such pads, a functionalized pad according to the present disclosure can include turbulence-creating structures intentionally focused on creating flow direction and turbulence with in the groove structures. For example, by casting small turbulence-creating structures into the sides and bottoms of the grooves, solutions can be slowed, agitated, and directed to precise locations on the pad. Such turbulence-creating structures can be created in the coating or surface of the mold. Turbulence-creating structures can be cast at a resolution of microns in some examples. In situ molding of such turbulence-creating structures creates the opportunity to introduce turbulence-creating structures to direct flow creating a more effective interaction of solution with the surface to be polished/planarized.

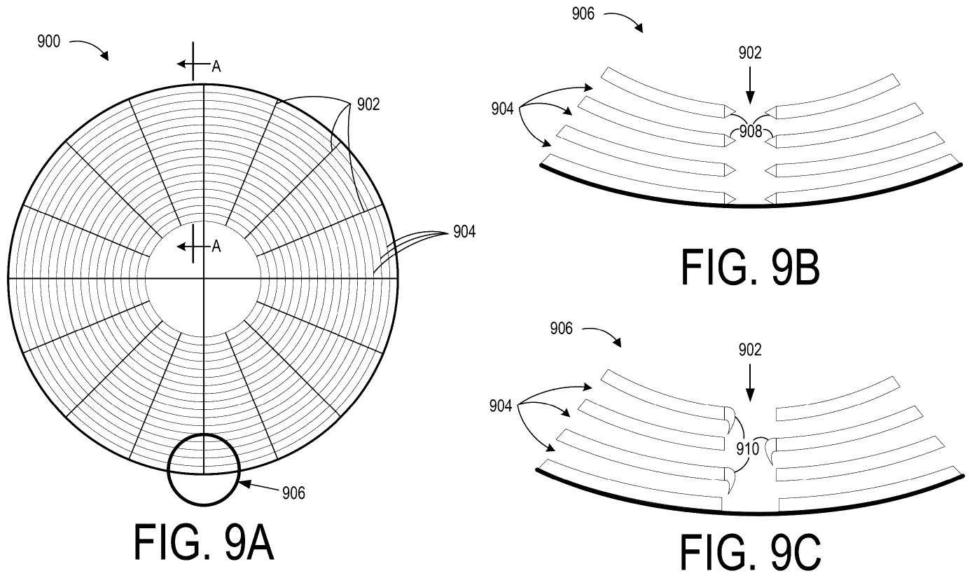

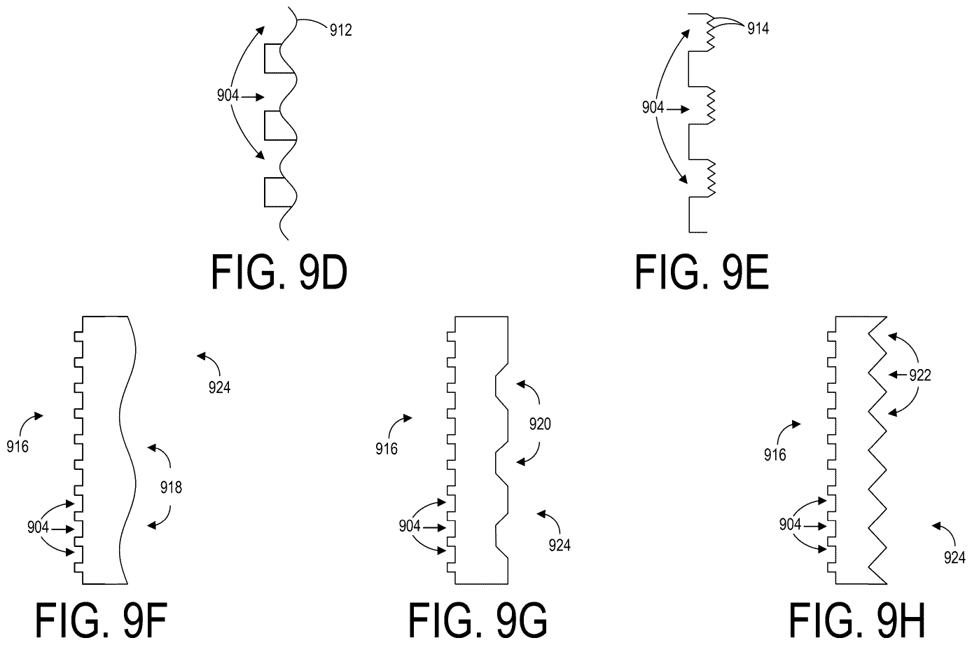

FIG. 9A schematically shows an example pad 900 that is suitable for use as the pad 104 of FIG. 1. The pad 900 comprises radial grooves 902 and concentric grooves 904. FIG. 9B and FIG. 9C schematically show a magnified view of a portion 906 of the pad 900 with turbulence-creating structures 908, 910 along the sides of the radial grooves 902. As shown in FIG. 9B, the turbulence-creating structures 908 can comprise angularly-shaped structures. Alternatively, as shown in FIG. 9C, the turbulence-creating structures 910 can comprise curved tapered structures. By including the turbulence-creating structures 908, 910 on the sides of the radial grooves 902 the flow pattern and/or residence time of the flowing or retained planarization solution can be modified. As described above, this modification can create a more effective interaction of a planarization solution with the surface to be polished/planarized.

Additionally, or alternatively, turbulence-creating structures can be formed at the bottom of the concentric grooves 904. FIG. 9D and FIG. 9E schematically show a magnified view of example turbulence-creating structures 912, 914 at the bottom of the concentric grooves 904 taken along line AA of FIG. 9A. For example, as shown in FIG. 9D, the turbulence-creating structures 912 can be sinusoidal shaped structures formed at the bottom of the concentric grooves 904. Alternatively, as shown in FIG. 9E, the turbulence-creating structures 914 can comprise triangular shaped structures formed at the bottom of the concentric grooves 904. As described above, by utilizing the turbulence-creating structures, solutions can be slowed, agitated, and directed to precise locations on the pad to create a more effective interaction of a planarization solution with the surface to be polished/planarized.

The disclosed turbulence-creating structures of FIGS. 9B-9E can be formed by casting and can be used to optimize the flow process and direct flows at a much more refined and controllable process than current grooves that are formed after casting. The disclosed structures also can be used to create a time period during which the solutions can dwell at desired locations of the pad. This can be beneficial where non-abrasive functionalized polishing pads are used. Such fluid dwell time can allow for the planarization solution to work effectively with the functionalized groups integral to the pad material. There is also a potential benefit where common abrasive slurries are used to distribute particles by size and or maintain agitation of the slurry over the pad surface.

The cast method used to create the structures can be highly reproducible, as the pads grooves are not cut in after casting. The structures allowing the unique flow are integral to the mold and either distributed/created in the coating of the grooves or machined intentionally into the grooves. This can increase contact and distribution of the solution with a wafer, which can result in better, more predictable contact of the wafer/surface. Optimal volumes of solution can be adjusted resulting in better use of solutions. Forming such structures by casting also allows the working/polishing surface to be mechanically resurfaced without effecting the distribution of the solution or micro structures in the grooves.

Returning to FIGS. 9A-9H, FIGS. 9F-9H schematically show a magnified view of the concentric grooves 904 on a substrate-contacting side 916 and example groove structures 918, 920, and 922 on a backside 924 taken along line AA of FIG. 9A. In some examples, the backside 924 can be configured to contact a platen that supports the pad 900 during planarization. In other examples, the backside 924 can be configured to contact an additional layer of the pad 900. As shown in FIGS. 9F-9H, the concentric grooves 904 comprise rectangular indentations along the substrate-contacting side 916. As shown in FIG. 9F, groove structures 918 can comprise sinusoidal shaped structures on the backside 924. Alternatively, as shown in FIG. 9G, groove structures 920 can comprise trapezoidal shaped structures on the backside 924. Further, as another alternative, as shown in FIG. 9H, groove structures 922 can comprise triangular shaped structures on the backside 924. Including the example groove structures on the backside 924 can provide for additional compressibility of the pad 900. This compressibility can help to avoid applying unwanted pressure against a substrate during planarization and, thus, can reduce shear stresses compared to conventional CMP processes. Additionally, including the example groove structures on the backside 924 can reduce or eliminate the need to add a foaming agent to a polymer matrix of the pad 900.

Further, the disclosure comprises configurations according to the following examples.

According to Example 1, a pad for performing abrasive-free chemical planarization of a substrate comprises a polymer layer configured to contact the substrate during the abrasive-free chemical planarization. The polymer layer comprises a plurality of reactive units covalently bonded within polymer chains. Each reactive unit comprises a functional group comprising one or more of a complexing agent or a hydrolyzing agent for performing the abrasive-free chemical planarization. The polymer layer comprises a plurality of molded grooves each containing turbulence-creating structures configured to cause turbulence in a planarization solution within the grooves during a planarization process.

Example 2 includes the pad of Example 1, wherein each reactive unit comprises the functional group.

Example 3 includes the pad of Example 1 or Example 2, wherein the functional groups are separated by oligomeric segments of the polymer chain.

Example 4 includes the pad of any of Example 1 to Example 3, wherein the functional groups are incorporated homogeneously throughout the polymer layer.

Example 5 includes the pad of any of Example 1 to Example 4, wherein the functional groups are bound to a substrate-facing surface of the polymer layer.

Example 6 includes the pad of any of Example 1 to Example 5, wherein the polymer layer comprises a polyurethane, and the functional groups are located on one or more of an isocyanate moiety of the polyurethane or a polyol moiety of the polyurethane.

Example 7 includes the pad of any of Example 1 to Example 6, wherein the polymer layer comprises a polyanhydride, and the functional groups are located on one or more of an anhydride moiety of the polyanhydride or a polyol moiety of the polyanhydride.

Example 8 includes the pad of any of Example 1 to Example 7, wherein the polymer layer comprises an epoxy, and the functional groups are located on one or more of an epoxide moiety of the epoxy or a polyol bound within an epoxy chain.

Example 9 includes the pad of any of Example 1 to Example 8, wherein the functional groups comprise one or more of a carboxylic acid, an amine, a sulfonic acid, an alcohol, a phosphonic acid, an amide, or a polyethylene.

Example 10 includes the pad of any of Example 1 to Example 9, wherein the functional groups comprise one or more of iminodisuccinic acid, ethylenediaminedisuccinic acid, glutamic acid, methylglycinediacetic acid, dicyanamide, or polydiallyldimethylammonium chloride.

Example 11 includes the pad of any of Example 1 to Example 10, wherein the pad comprises one or more of microspheres or fillers, wherein the one or more of the microspheres or the fillers each comprises a polymer and functional groups bonded to the polymer, wherein the one or more of the microspheres or the fillers are not covalently bonded to the polymer layer of the pad.

According to Example 12, a pad for performing abrasive-free chemical planarization of a substrate comprises a first polymer layer configured to contact the substrate during the abrasive-free chemical planarization. The first polymer layer comprises a plurality of reactive units covalently bonded within polymer chains. Each reactive unit comprises a functional group comprising one or more of a complexing agent or a hydrolyzing agent for performing the abrasive-free chemical planarization. The pad further comprises a second polymer layer positioned on an opposite side of the first polymer layer as a substrate-contacting side of the first polymer layer.

Example 13 includes the pad of Example 12, wherein the second polymer layer is more compressible than the first polymer layer.

Example 14 includes the pad of Example 12 or Example 13, wherein the first polymer layer and the second polymer layer each comprise a porous polymer, and wherein the first polymer layer has a smaller pore fraction than the second polymer layer.

Example 15 includes the pad of any of Example 12 to Example 14, wherein the first polymer layer comprises a textured substrate-facing surface.

Example 16 includes the pad of any of Example 12 to Example 15, wherein the functional groups comprise one or more of a carboxylic acid, an amine, a sulfonic acid, an alcohol, a phosphonic acid, an amide, or a polyethylene.

Example 17 includes the pad of any of Example 12 to Example 16, wherein the functional groups comprise one or more of iminodisuccinic acid, ethylenediaminedisuccinic acid, glutamic acid, methylglycinediacetic acid, dicyanamide, or polydiallyldimethylammonium chloride.

According to Example 18, a pad for performing abrasive-free chemical planarization of a substrate comprises a polymer layer located configured to contact the substrate during the abrasive-free chemical planarization. The polymer layer comprises a plurality of reactive units covalently bonded within polymer chains. Each reactive unit comprises a functional group comprising one or more of a complexing agent or a hydrolyzing agent for performing the abrasive-free chemical planarization. The pad further comprises groove structures configured to provide compressibility for the pad.

Example 19 includes the pad of Example 18, wherein the groove structures are configured to contact an additional polymer layer of the pad.

Example 20 includes the pad of Example 18 or Example 19, wherein the groove structures are configured to contact a platen configured to support the pad.

This disclosure is presented by way of example and with reference to the associated drawing figures. Components, process steps, and other elements that can be substantially the same in one or more of the figures are identified coordinately and are described with minimal repetition. It will be noted, however, that elements identified coordinately can also differ to some degree. It will be further noted that some figures can be schematic and not drawn to scale. The various drawing scales, aspect ratios, and numbers of components shown in the figures can be purposely distorted to make certain features or relationships easier to see.

“And/or” as used herein is defined as the inclusive or V, as specified by the following truth table:

| A | B | A ∨ B |
|---|---|---|
| True | True | True |
| True | False | True |
| False | True | True |
| False | False | False |

The terminology “one or more of A or B” as used herein comprises A, B, or a combination of A and B. The terminology “one or more of A, B, or C” is equivalent to A, B, and/or C. As such, “one or more of A, B, or C” as used herein comprises A individually, B individually, C individually, a combination of A and B, a combination of A and C, a combination of B and C, or a combination of A, B and C.

It will be understood that the configurations and/or approaches described herein are example in nature, and that these specific embodiments or examples are not to be considered in a limiting sense, because numerous variations are possible. The specific routines or methods described herein can represent one or more of any number of strategies. As such, various acts illustrated and/or described can be performed in the sequence illustrated and/or described, in other sequences, in parallel, or omitted. Likewise, the order of the above-described processes can be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A pad for performing abrasive-free chemical planarization of a substrate, the pad comprising:
a polymer layer configured to contact the substrate during the abrasive-free chemical planarization, wherein the polymer layer comprises a plurality of reactive units covalently bonded within polymer chains, each reactive unit comprising a functional group comprising one or more of a complexing agent or a hydrolyzing agent for performing the abrasive-free chemical planarization, and wherein the polymer layer comprises a plurality of molded grooves each containing turbulence-creating structures configured to cause turbulence in a planarization solution within the grooves during a planarization process.

2. The pad of claim 1, wherein each reactive unit comprises the functional group.

3. The pad of claim 1, wherein the functional groups are separated by oligomeric segments of the polymer chain.

4. The pad of claim 1, wherein the functional groups are incorporated homogeneously throughout the polymer layer.

5. The pad of claim 1, wherein the functional groups are bound to a substrate-facing surface of the polymer layer.

6. The pad of claim 1, wherein the polymer layer comprises a polyurethane, and the functional groups are located on one or more of an isocyanate moiety of the polyurethane or a polyol moiety of the polyurethane.

7. The pad of claim 1, wherein the polymer layer comprises a polyanhydride, and the functional groups are located on one or more of an anhydride moiety of the polyanhydride or a polyol moiety of the polyanhydride.

8. The pad of claim 1, wherein the polymer layer comprises an epoxy, and the functional groups are located on one or more of an epoxide moiety of the epoxy or a polyol bound within an epoxy chain.

9. The pad of claim 1, wherein the functional groups comprise one or more of a carboxylic acid, an amine, a sulfonic acid, an alcohol, a phosphonic acid, an amide, or a polyethylene.

10. The pad of claim 1, wherein the functional groups comprise one or more of iminodisuccinic acid, ethylenediaminedisuccinic acid, glutamic acid, methylglycinediacetic acid, dicyanamide, or polydiallyldimethylammonium chloride.

11. The pad of claim 1, wherein the pad comprises one or more of microspheres or fillers, wherein the one or more of the microspheres or the fillers each comprises a polymer and functional groups bonded to the polymer, wherein the one or more of the microspheres or the fillers are not covalently bonded to the polymer layer of the pad.

12. A pad for performing abrasive-free chemical planarization of a substrate, the pad comprising:
a first polymer layer configured to contact the substrate during the abrasive-free chemical planarization, wherein the first polymer layer comprises a plurality of reactive units covalently bonded within polymer chains, each reactive unit comprising a functional group comprising one or more of a complexing agent or a hydrolyzing agent for performing the abrasive-free chemical planarization; and
a second polymer layer positioned on an opposite side of the first polymer layer as a substrate-contacting side of the first polymer layer.

13. The pad of claim 12, wherein the second polymer layer is more compressible than the first polymer layer.

14. The pad of claim 12, wherein the first polymer layer and the second polymer layer each comprise a porous polymer, and wherein the first polymer layer has a smaller pore fraction than the second polymer layer.

15. The pad of claim 12, wherein the first polymer layer comprises a textured substrate-facing surface.

16. The pad of claim 12, wherein the functional groups comprise one or more of a carboxylic acid, an amine, a sulfonic acid, an alcohol, a phosphonic acid, an amide, or a polyethylene.

17. The pad of claim 12, wherein the functional groups comprise one or more of iminodisuccinic acid, ethylenediaminedisuccinic acid, glutamic acid, methylglycinediacetic acid, dicyanamide, or polydiallyldimethylammonium chloride.

18. A pad for performing abrasive-free chemical planarization of a substrate, the pad comprising:
a polymer layer located configured to contact the substrate during the abrasive-free chemical planarization, wherein the polymer layer comprises a plurality of reactive units covalently bonded within polymer chains, each reactive unit comprising a functional group comprising one or more of a complexing agent or a hydrolyzing agent for performing the abrasive-free chemical planarization; and
groove structures configured to provide compressibility for the pad.

19. The pad of claim 18, wherein the groove structures are configured to contact an additional polymer layer of the pad.

20. The pad of claim 18, wherein the groove structures are configured to contact a platen configured to support the pad.
